(19) United States
(12) Patent Application Publication
(10) Pub. No.: US 2021/0020441 A1
(43) Pub. Date: Jan. 21, 2021

(54) IN SITU INVERSE MASK PATTERNING

(71) Applicant: Lam Research Corporation, Fremont, CA (US)

(72) Inventors: Juan VALDIVIA, Fremont, CA (US); Yasushi ISHIKAWA, Fremont, CA (US); Yoko YAMAGUCHI, Union City, CA (US)

(21) Appl. No.: 17/040,922

(22) PCT Filed: Mar. 29, 2019
(86) PCT No.: PCT/US2019/024861

§ 371 Date: Sep. 23, 2020

Related U.S. Application Data
(60) Provisional application No. 62/651,900, filed on Apr. 3, 2018.

(51) Int. Cl. H01L 21/033; G03F 7/20; G03F 1/22

(52) U.S. Cl. CPC H01L 21/0337; G03F 1/22; G03F 7/70033

(57) ABSTRACT

A method for etching features in a stack below a mask with features is provided. A fill layer is deposited on the mask, wherein the fill layer fills the features of the mask. The fill layer is etched back to expose the mask. The mask is selectively removed with respect to the fill layer. The stack is etched using the fill layer as a mask.

### CROSS REFERENCE TO RELATED APPLICATION

This application claims the benefit of priority of U.S. Provisional Application No. 62/651,900 dated Apr. 3, 2018, which is incorporated herein by reference for all purposes.

### BACKGROUND

The disclosure relates to a method of forming semiconductor devices on a semiconductor wafer.

In the formation of semiconductor devices, features are etched using a patterned mask. The patterned mask may be formed from a photoresist material.

### SUMMARY

To achieve the foregoing and in accordance with the purpose of the present disclosure, a method for etching features in a stack below a mask with features is provided. A fill layer is deposited on the mask, wherein the fill layer fills the features of the mask. The fill layer is etched back to expose the mask. The mask is selectively removed with respect to the fill layer. The stack is etched using the fill layer as a mask.

These and other features of the present disclosure will be described in more details below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-F are perspective views of a stack processed according to an embodiment.

FIGS. 3A-E are cross-sectional views of a stack processed according to another embodiment.

FIG. 4 is a schematic view of a etch chamber that may be used in an embodiment.

FIG. 5 is a schematic view of a computer system that may be used in practicing an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

An etch and atomic layer passivation (ALP) process can be used to invert a pattern from photoresist (PR), such as extreme ultraviolet photoresist (EUV PR) mask, into a hardmask pattern. By doing so, patterning improvements can be achieved. The entire process may be done on in a processing chamber with an ability to perform atomic layer deposition (ALD). In the alternative, the process may be done in multiple process chambers.

An embodiment may be used to improve the specifications of the mask features such as critical dimension uniformity (CDU), global (full wafer) critical dimension uniformity (GCDU), line width roughness (LWR), line edge roughness (LER), the local critical dimension uniformity (LCDU), the ratio of the major axis to the minor axis (Major/Minor), and the ratio of the minor axis to the major axis (Minor/Major).

An embodiment is used to etch under layers, below a bottom antireflective coating (BARC) layer, below a photoresist mask in a stack, according to the following process. 1) A Process Pretreatment (PPT) treats the photoresist to increase the rigidity of the photoresist (PR). 2) A plasma etch treatment improves PR height and modifies the CDs of the features. 3) A vertical etch of exposed parts of the BARC layer is used to expose non-carbon based under layers. 4) An oxide ALD is used to fully encapsulate the PR and fill the features. 5) The ALD oxide is etched back to expose the PR. 6) The PR is stripped away to reveal the final reversed/inverted pattern. The final oxide mask is the desired pattern and is now conferred with the structure specification from the starting PR mask pattern.

If the desired pattern was resolved with the PR directly the resulting structure specifications would have been of lower quality. A major drawback of a PR mask with current methodologies is a high variability between similar feature patterns. Feature to feature variability can be improved with the mask inversion of this embodiment. Another benefit is the oxide mask can be used to etch under layers with higher selectivity than a PR mask. Additionally, the final oxide mask results in a better shape vs. a PR mask of the same pattern.

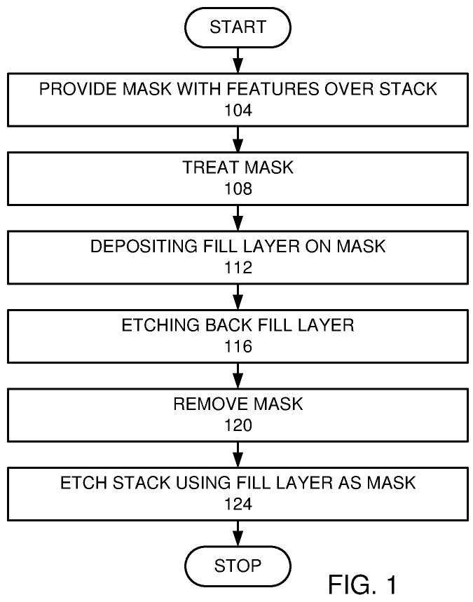

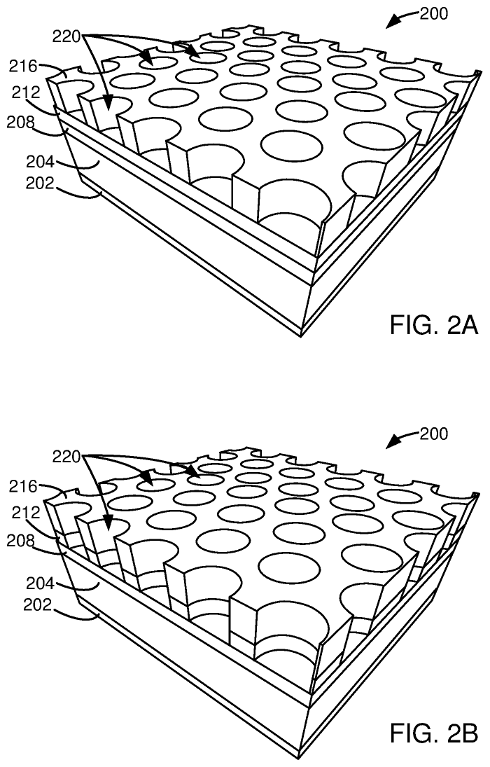

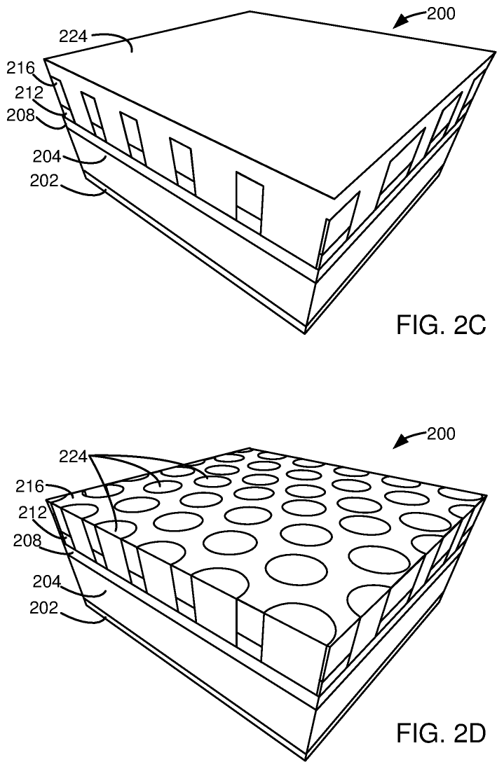

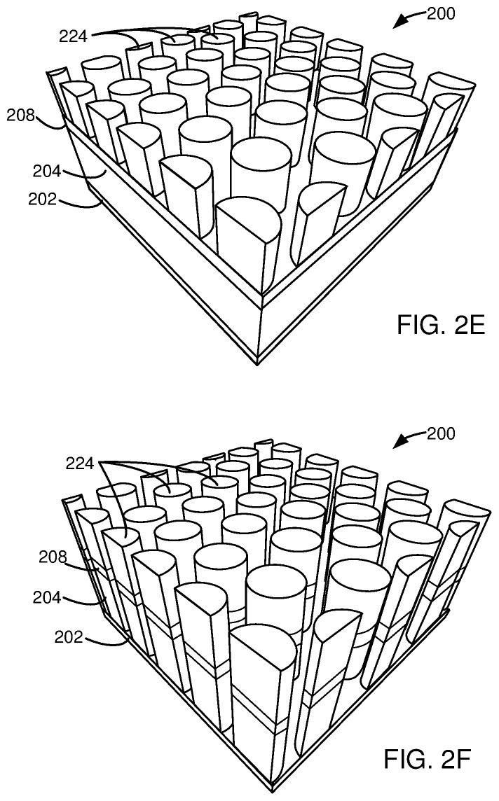

To facilitate understanding, FIG. 1 is a high level flow chart of an embodiment. A mask with features is provided over a stack (step 104). FIG. 2A is a perspective view of a stack 200. The stack comprises a substrate 202 with an under layer 204 over the substrate 202. In this embodiment, a dielectric antireflective coating (DARC) layer 208 is a non-carbon based layer over the under layer 204. The DARC layer 208 forms an additional layer of the stack 200. A BARC layer 212 is over the DARC layer 208. A mask 216 with features 220 is over the BARC layer 212. In this embodiment, the mask 216 is a PR mask of EUV PR. In this embodiment, the mask 216 forms features 220 in the shape of a plurality of cylindrical holes.

In order to increase the material rigidity for subsequent etch steps, the mask 216 is treated (step 108). In this embodiment, the treatment is a first pre-process treatment (PPT). The incoming mask pattern of holes has better specifications than an inverted pattern of pillars, but is still very soft and needs the material treatment to prevent the subsequent etch steps from removing excessive photoresist. In an embodiment, a low pressure of 2 milliTorr (mTorr) to 80 mTorr is provided in the process chamber. A treatment gas of a hydrofluorocarbon (CₓH_{y}F_{z}) is flowed into the process chamber and formed into a plasma, in order to increase PR structural performance. Gas additions are used to improve rigidity. Gases additions may include the one or more of oxygen (O₂), sulfur dioxide (SO₂), carbonyl sulfide (COS), fluoromethane (CH₃F), difluoromethane (CH₂F₂), trifluoromethane (CHF₃), carbon tetrafluoride (CF₄), nitrogen (N₂), argon (Ar), helium (He), chlorine (Cl₂), hydrogen bromide (HBr), and krypton (Kr). The process is run for 5 to 60 seconds to maximize the rigidity of the PR. Additional modifications in plasma intensity and temperature control allow for discreet process tuning relative the PR material being treated.

In this embodiment, the treating the mask (step 108) further comprises a follow-up PR shaping step. The follow-up PR shaping step is used to fill in voids in the initial mask structure and establish a desired CD prior to the following deposition. In this embodiment, the chamber is subjected to a low pressure in the range of 2 mTorr to 80 mTorr. A treatment process gas of CₓH_{y}F_{z} is flowed into the process chamber. Additional gases of one or more of COS, N2, Ar, He, Kr, and methane (CH₄) are added to control vertical and lateral deposition rates. The gases are formed into a plasma. The void fill ability is also controlled by proper ratio control of chemistry. The plasma is controlled with a low power output of 50-1000 watts. The process improves the shape and uniformity of the features 220.

Since this embodiment has a carbon based BARC layer 212, parts of the BARC layer 212 not masked by the mask 216 are etched away in order to extend the features 220. The exposed carbon based BARC layer 212 is etched in order to increase the adhesion of a silicon based fill layer. In this embodiment, in order to etch the BARC layer 212, a gas of CₓH_{y}F_{z} is flowed into the process chamber at a low pressure. Gas additions are added to improve selectivity in order to selectively etch the BARC layer 212 with respect to the mask 216 without damaging of under layers. The gas additions may be one or more of the following: O₂, SO₂, COS, CH₃F, CH₂F₂, CHF₃, CF₄, N₂, Ar, He, Cl₂, HBr, and Kr. FIG. 2B is a perspective view of the stack after the BARC layer 212 has been etched. The BARC layer 212 has been etched back to expose parts of the DARC layer 208. This process provides a high selectivity of etching the BARC layer 212 with respect to the mask 216.

After the BARC layer 212 is etched, a fill layer is deposited (step 112) to completely fill the features 220 and to encapsulate the surface of the stack 200. In this embodiment, the fill layer is deposited (step 112) by providing an ALD that is highly conformal and covers the mask 216 and completely fills the features 220. The ALD material in this embodiment can be of any silicon containing film (e.g. SiₓO_{y}, SiₓN_{y}, SiₓO_{y}N_{z}) or films with a high selectivity to PR strip removal like metals and metal oxides. (e.g. TiN, WₓO_{y}). The fill layer properties are controlled to have a high selectivity to the mask 216 and under layers.

In an embodiment in order to provide the ALD, a liquid silicon containing precursor is vaporized and delivered in vapor form to dose the stack 200 to saturation, thereby forming a layer of precursor on the stack. In this example, the precursor has a composition of the general type C(x)H(y)N(z)O(a)Si(b). In some embodiments, the precursor has one of the following compositions: N,N,N′,N′,N″,N″-Hexamethylsilanetriamine (C₆H₁₉N₃Si, C₈H₂₂N₂Si), (3-Aminopropyl)triethoxysilane (C₉H₂₃NO₃Si), and Tetra(isopropoxy)silane (C₁₂H₂₈O₄Si). In this example, the providing of the precursor is plasmaless. The precursor has a silicon function group, which forms a monolayer on the stack 200, since the precursor does not attach to another precursor.

Once the stack 200 is dosed with the precursor, the delivery of the precursor vapor is stopped. Then a purge step is provided to purge out excessive precursor that lingers in the chamber. The precursor is then converted. In one embodiment, this is accomplished by subjecting the stack 200 to a flash process. The flash process includes providing a flash gas of oxygen (O₂). In this example, a power of 500 to 3000 watts is provided at 13.56 MHz to transform the flash gas into a plasma. A pressure of 20 mTorr to 100 mTorr is provided. This flash process is referred to as an “O₂ flash” operation, as the time during which the power is delivered is relatively fast, e.g., between about 0.5 second and about 4 seconds. The O₂ flash operation forms a silicon oxide monolayer on the stack 200 using the monolayer of the silicon containing precursor. The cycle may then be repeated.

The ALD in this embodiment can use any number of wetting agents in other embodiments. The process can be carried out in the same process chamber with the previous etch steps or in a separate deposition/etch chamber. FIG. 2C is a perspective view of the stack after the fill layer 224 has been deposited. The fill layer 224 not only covers the mask 216 but also completely fills the features 220 with silicon oxide (SiO₂). Depending on the ALD recipe parameters, the fill layer 224 can further change the mask 216 structure. The deposition of the fill layer 224 (step 112) may remove footers of the mask 216 or provide CD adjustments.

Once the mask 216 is encapsulated, the mask 216 needs to be exposed for removal. As a result, the fill layer 224 is etched back (step 116). In this embodiment, the etch back of the fill layer 224 (step 116) is a form of planarization. The etch back of the fill layer 224 (step 116) must have a high selectivity required to prevent profile degradation of the fill layer 224. A selectivity of 1:1 or greater to the mask 216 will result in low fill layer 224 degradation. In an embodiment, an etch back gas comprising CₓH_{y}F_{z} and an additional gas of at least one of O₂, SO₂, COS, CH₃F, CH₂F₂, CHF₃, CF₄, N₂, Ar, He, Cl₂, HBr, and Kr are flowed into the process chamber. A plasma is formed from the etch back gas. FIG. 2D is a perspective view of the stack after the fill layer 224 has been etched back. The oxide film properties may be controlled with parameters in the etch step.

With the exposure of the mask 216 complete, the next step is to remove the mask (step 120) with an etch that selectivity etches the mask 216 with respect to the fill layer 224. A mask etch gas of O₂ is provided to the process chamber at a low pressure. Additional gases may be added to improve residue removal. The additional gases include at least one of COS, SO₂, CF₄, N₂, Ar, He, Cl₂, HBr, and Kr. FIG. 2E is a perspective view of the stack 200 after the mask 216 has been removed.

With the mask 216 removed, the pillars formed from the remaining fill layer 224 are ready to act as a mask for etching the DARC layer 208 and the under layer 204 to provide the desired pattern. The fill layer 224 forms a pillar pattern mask. The stack 200 is etched using the fill layer 224 as a mask (step 124). In this embodiment, a halogen based plasma may be used to etch the stack 200 (step 124).

FIG. 2F is a perspective view of the stack 200 after DARC layer 208 and the under layer 204 have been etched using the fill layer 224 as a mask (step 124). The DARC layer 208 or the fill layer 224 or another underlying layer may be used as a hardmask to etch the under layer 204.

In this embodiment, the fill layer 224 forms pillars. For conventional processes where a photoresist mask forms pillars, it has been found resulting pillars in underlying layers have defects and poor CD uniformity. By instead forming a pattern of holes in a photoresist mask and then forming ALD oxide pillars, the resulting pillars have fewer defects and improved CD uniformity. A conventional etch process using a conventional photoresist mask resulted in 3.7 nm GCDU. An embodiment resulted in 3.2 nm GCDU post hard mask under layer etch.

In this embodiment, the mask 216 is relatively thin with an average thickness of no more than 50 nm. In an embodiment, the mask 216 has an average thickness of between 20 nm to 50 nm, inclusive. In another embodiment, the mask 216 has an average thickness of between 20 nm to 30 nm, inclusive. An average thickness is used since at such a small thickness, variation of the thickness is significant with respect to the total thickness. For EUV PR, the mask 216 thickness may vary by about 15 nm from average. Therefore, having an average thickness of at least 20 nm with a variation of about 15 nm means that the mask would not at any location be less than 5 nm. An upper limit on the average thickness of the mask 216 is set by the time required to fill the features 220. If the mask 216 is too thick, it will take too much time to fill the features 220.

In the specification and claims, filling the features 220 means that the features 220 are completely filled. In completely filling the features 220, within the features 220 the fill layer 224 is deposited to a thickness of at least the average thickness of the mask 216. More preferably, the fill layer 224 fills the features 220 to with a thickness greater than the thickest part of the mask 216.

The requirement and ability to use a thin mask 216 allows the use of a higher resolution mask 216. Thicker masks 216 decrease resolution and increase distortion such as wiggling and sagging. In this embodiment, the holes have a width in the range of 20 to 50 nm.

Such a fill is different than deposition in a spacer deposition process. In a spacer deposition process, a conformal layer is formed. The thickness of the spacer layer at the bottom of the features between masks is less than the thickness of the mask. Therefore, the spacer layer does not fill the features, as defined in the specification and claims. In a spacer process, the spacer material at the bottom of the features is etched away to form the spacer. Therefore, in the formation of spacers, it is not desirable to have the thickness of the spacer material at the bottom of the features to be as thick as the mask. In addition, a spacer process requires the formation of vertical spacers. As a result, the mask would be thicker than 50 nm in order to form a vertical spacer. In addition, in a spacer process, within a feature, two or more sidewalls are formed. A sidewall spacer process that forms two are more sidewalls in each hole is different from various embodiments, where only one pillar is formed from each feature hole.

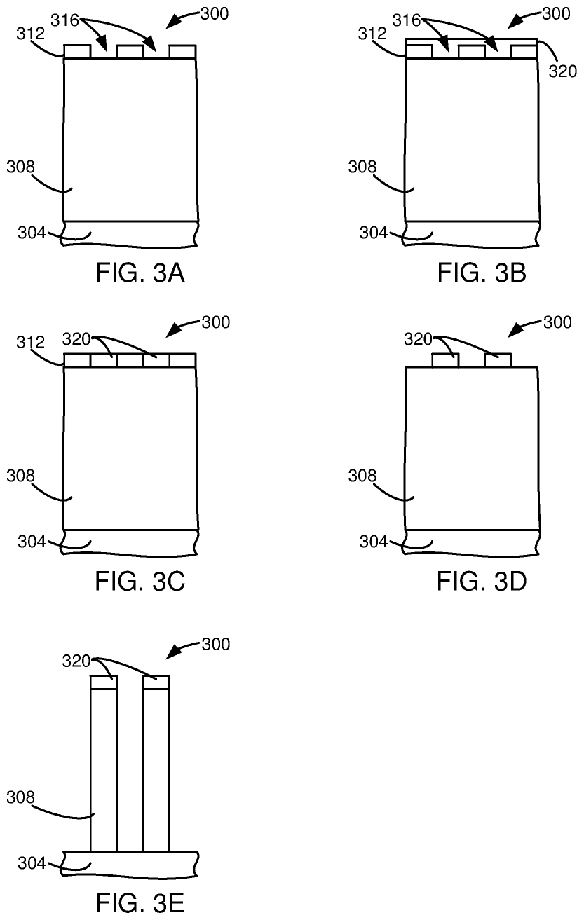

FIG. 3A is a schematic cross-sectional view of a stack 300 processed in another embodiment. The stack 300 comprises a substrate 304. An under layer 308 may be one or more layers over the substrate 304. A mask 312 is formed over the under layer 308 (step 104). The mask 312 comprises lines with lengths extending into the page and features 316 between the lines. The features 316 and the lines form a trench pattern with a plurality of trenches. The mask 312 is treated (step 108) to improve linearity of the mask 312 and reduce sagging and curving of the mask 312. In this embodiment, the mask 312 is a carbon based mask 312.

A fill layer is deposited on the mask 312 completely filling the features 316 (step 112). Either an ALD or plasma enhanced chemical vapor deposition (PECVD) is used to deposit the fill layer. In this example, the fill layer is a silicon containing material, such as being silicon oxide (SiO₂) based. FIG. 3B is a schematic cross-sectional view of a stack 300 after the fill layer 320 has been deposited (step 112).

The fill layer 320 is etched back (step 116) to expose the mask 312. FIG. 3C is a schematic cross-sectional view of a stack 300 after the fill layer 320 has been etched back (step 116). The mask 312 is removed (step 120). FIG. 3D is a schematic cross-sectional view of a stack 300 after the mask 312 has been removed (step 120). The fill layer 320 forms a wall pattern mask. The under layer 308 is etched using the fill layer 320 as a mask (step 124). FIG. 3E is a schematic cross-sectional view of a stack 300 after the under layer 308 has been etched (step 124). The resulting stack provides walls or lines of the under layer 308 below the areas where the mask 312 had features 316 or holes. Each feature 316 of the mask 312 is used to form only one wall. This would be different than a double patterning process. In a double patterning process, sidewalls are used to provide two or more walls under each feature. In other embodiments, instead of cylindrical holes or trenches, the features in the mask 312 may have other shapes in order to form a fill layer with other shapes. In this embodiment, the fill layer 320 is subsequently removed.

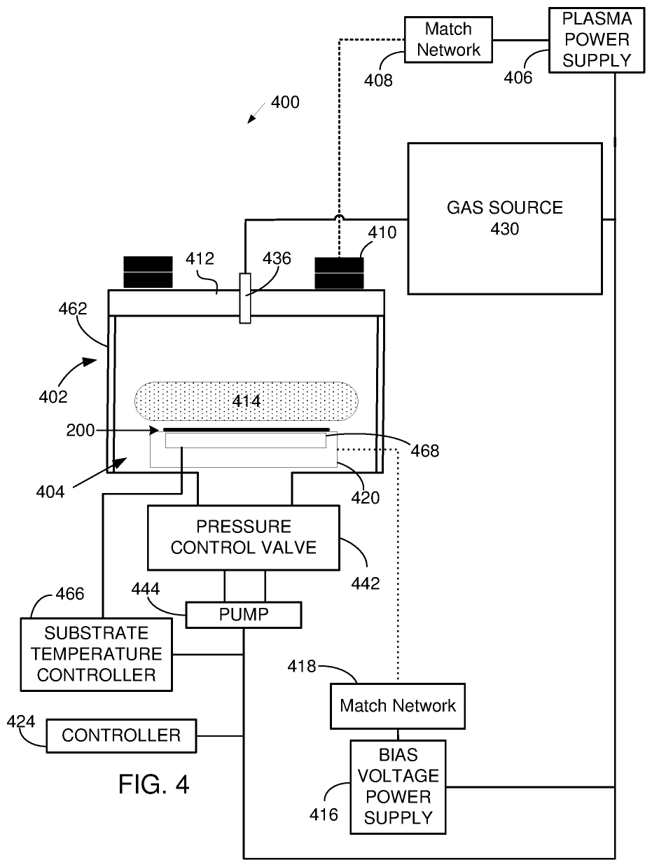

FIG. 4 schematically illustrates an example of a plasma processing system 400 which may be used to process a stack 200 in accordance with one embodiment. The plasma processing system 400 includes a plasma reactor 402 having a plasma processing chamber 404, enclosed by a chamber wall 462. A plasma power supply 406, tuned by a match network 408, supplies power to a TCP coil 410 located near a power window 412 to create a plasma 414 in the plasma processing chamber 404 by providing an inductively coupled power. The TCP coil (upper power source) 410 may be configured to produce a uniform diffusion profile within the plasma processing chamber 404. For example, the TCP coil 410 may be configured to generate a toroidal power distribution in the plasma 414. The power window 412 is provided to separate the TCP coil 410 from the plasma processing chamber 404 while allowing energy to pass from the TCP coil 410 to the plasma processing chamber 404. A wafer bias voltage power supply 416 tuned by a match network 418 provides power to an electrode 420 to set the bias voltage on the stack 200. The electrode 420 provides a chuck for the stack 200, where the electrode 420 acts as an electrostatic chuck. A substrate temperature controller 466 is controllably connected to a Peltier heater/cooler 468. A controller 424 sets points for the plasma power supply 406, the substrate temperature controller 466, and the wafer bias voltage power supply 416.

The plasma power supply 406 and the wafer bias voltage power supply 416 may be configured to operate at specific radio frequencies such as 13.56 MHz, 27 MHz, 2 MHz, 1 MHz, 400 kHz, or combinations thereof. Plasma power supply 406 and wafer bias voltage power supply 416 may be appropriately sized to supply a range of powers in order to achieve desired process performance. For example, in one embodiment, the plasma power supply 406 may supply the power in a range of 50 to 5000 Watts, and the wafer bias voltage power supply 416 may supply a bias voltage in a range of 20 to 2000 V. In addition, the TCP coil 410 and/or the electrode 420 may be comprised of two or more sub-coils or sub-electrodes, which may be powered by a single power supply or powered by multiple power supplies.

As shown in FIG. 4, the plasma processing system 400 further includes a gas source 430. The gas source 430 provides gas or remote plasma to a feed 436 in the form of a nozzle. The process gases and byproducts are removed from the plasma processing chamber 404 via a pressure control valve 442 and a pump 444. The pressure control valve 442 and the pump 444 also serve to maintain a particular pressure within the plasma processing chamber 404. The gas source 430 is controlled by the controller 424. A Kiyo® by Lam Research Corp. of Fremont, Calif., may be used to practice an embodiment.

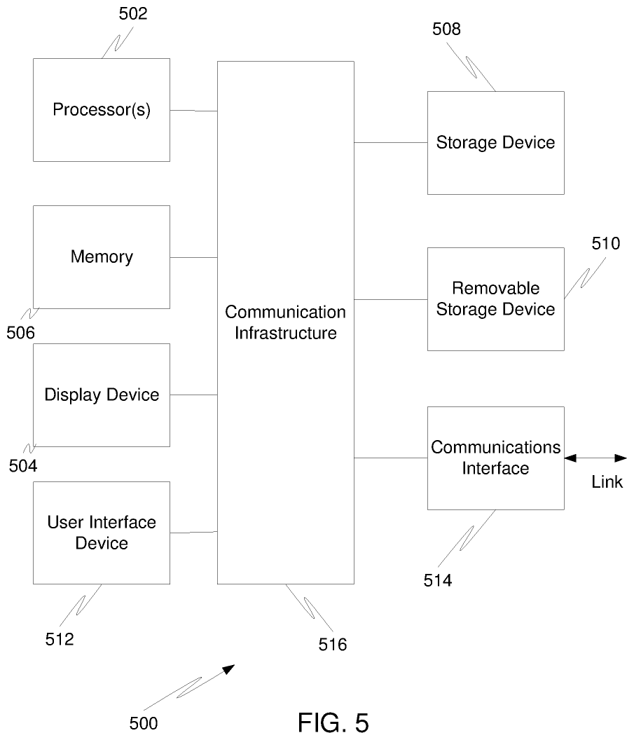

FIG. 5 is a high level block diagram showing a computer system 500, which is suitable for implementing a controller 424 used in embodiments. The computer system may have many physical forms ranging from an integrated circuit, a printed circuit board, and a small handheld device, up to a huge super computer. The computer system 500 includes one or more processors 502, and further can include an electronic display device 504 (for displaying graphics, text, and other data), a main memory 506 (e.g., random access memory (RAM)), storage device 508 (e.g., hard disk drive), removable storage device 510 (e.g., optical disk drive), user interface devices 512 (e.g., keyboards, touch screens, keypads, mice or other pointing devices, etc.), and a communication interface 514 (e.g., wireless network interface). The communication interface 514 allows software and data to be transferred between the computer system 500 and external devices via a link. The system may also include a communications infrastructure 516 (e.g., a communications bus, cross-over bar, or network) to which the aforementioned devices/modules are connected.

Information transferred via communications interface 514 may be in the form of signals such as electronic, electromagnetic, optical, or other signals capable of being received by communications interface 514, via a communication link that carries signals and may be implemented using wire or cable, fiber optics, a phone line, a cellular phone link, a radio frequency link, and/or other communication channels. With such a communications interface, it is contemplated that the one or more processors 502 might receive information from a network, or might output information to the network in the course of performing the above-described method steps. Furthermore, method embodiments may execute solely upon the processors or may execute over a network, such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory, and shall not be construed to cover transitory subject matter, such as carrier waves or signals. Examples of computer code include machine code, such as one produced by a compiler, and files containing higher level code that are executed by a computer using an interpreter. Computer readable media may also be computer code transmitted by a computer data signal embodied in a carrier wave and representing a sequence of instructions that are executable by a processor.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

1. A method for etching features in a stack below a mask with features, comprising:
depositing a fill layer on the mask, wherein the fill layer fills the features of the mask;
etching back the fill layer to expose the mask;
selectively removing the mask with respect to the fill layer; and
etching the stack using the fill layer as a mask.

2. The method, as recited in claim 1, wherein the mask has an average thickness of between 20 nm to 50 nm inclusive.

3. The method, as recited in claim 1, wherein the mask forms a hole pattern with a plurality of holes and wherein the fill layer forms a pillar pattern mask.

4. The method, as recited in claim 3, wherein the etching the stack using the fill layer as a mask forms a plurality of pillars.

5. The method, as recited in claim 4, wherein each hole of the plurality of holes of the hole pattern is used to form only one pillar of the plurality of pillars.

6. The method, as recited in claim 1, wherein the mask forms a trench pattern with a plurality of trenches and wherein the fill layer forms a wall pattern mask.

7. The method, as recited in claim 6, wherein the etching the stack using the fill layer as a mask forms a plurality of walls.

8. The method, as recited in claim 7, wherein each trench of the plurality of trenches of the trench pattern is used to form only one wall of the plurality of walls.

9. The method, as recited in claim 1, wherein the mask is a photoresist mask.

10. The method, as recited in claim 9, further comprising pretreating the photoresist mask.

11. The method, as recited in claim 10, wherein the mask further comprises a carbon based bottom antireflective coating.

12. The method, as recited in claim 11, further comprising etching exposed parts of the carbon based bottom antireflective coating before depositing the fill layer.

13. The method, as recited in claim 1, wherein the mask is an EUV photoresist mask.

14. The method, as recited in claim 1, wherein the depositing the fill layer comprises one of atomic layer deposition or plasma enhanced chemical vapor deposition.

15. The method, as recited in claim 1, wherein the stack comprises a non-carbon based dielectric antireflective coating.

16. The method, as recited in claim 14, wherein the fill layer is of at least one of a silicon containing material, metal, and metal oxide material and wherein the fill layer completely fills the features of the mask.

17. The method, as recited in claim 1, wherein the fill layer is of at least one of a silicon containing material, metal, and metal oxide material and wherein the fill layer completely fills the features of the mask.
